(19) United States
(12) Patent Application Publication
(10) Pub. No.: US 2005/0195568 A1
(43) Pub. Date: Sep. 8, 2005

(54) Active convective air scoop cooler

(76) Inventor: Daniel Shyr, Taipei City (TW)

Correspondence Address: Keith Kline;PRO-TECHTOR INTERNATIONAL SERVICES, 20775 Norada Court, Saratoga, CA, 95070-3018, US

(21) Appl. No.: 10/887,504

(22) Filed: Jul. 7, 2004

(30) Foreign Application Priority Data
Mar. 8, 2004 (TW) 093106090

(51) Int. Cl. H05K 7/20

(52) U.S. Cl. 361/695

(57) ABSTRACT

The present invention relates to an active convective air scoop cooler, which comprises a duct and a fastener module. The duct attach and couple with a chassis of electronic system by the fastener module. Two ends of the duct open and a fan is set integrated with the duct blowing an active convective airflow. The duct covers the microprocessor and/or heat dissipating electronic components on the mainboard of the electronic system. The active convective airflow increases efficiency of cooling of electronic system. An extended movable swapping cover coupled with the duct covers extended extra second microprocessor in situation of server, or other electronic components when needed. A soundproof stuff is laid inside the duct to reduce buzz noise.

### BACKGROUND OF THE INVENTION

1. Field of the Invention

The present invention relates to an active convective air scoop cooler of a computer or an electronics system, and especially to a duct integrated with a fan, which covers microprocessors and other electronic components or devices on mainboard. With two ends open in chassis, fans produce an active convection of air induction and exhaust to cool electronic components or devices, and also soundproof stuff laid inside the duct can reduce noise.

2. Description of the Related Art

Electronics industry develops and upgrades soon. Integrated circuits (ICs) are getting smaller and consume more power, and also produce much heat, especially some modern microprocessors like Central Processing Units (CPUs) in computer. Heat will decrease efficiencies of electronic components, damage or even make components burnout. In computer system, for example, ICs, chips, and other electronic components are integrated onto a printed circuit board or mainboard and installed in a closed chassis. These are all heat sources dissipating heat and increasing temperature in internal chassis.

Fans and radiators are most used to transfer heat in prior art. A radiator with fins is attached onto a heat dissipating electronic component to enlarge surface, and a fan makes active airflow to convect. This simple technique can transfer heat efficiently only when the environment temperature is much lower than heat source, and this cooling assembly or system can only decrease temperature of specific component. In closed chassis, the prior art only transfer heat out of component into the chassis, and after a period of working time, the whole temperature inside will arise and heat transferring efficiency get lower and lower. For further solution, some prior designs set fans on sides of chassis blowing air in and out, but limited in wires and components obstructing inside, the convection is still slow and efficiency raises only few. Besides, more fans mean more noises of motors or airflow. High frequency buzz makes users uncomfortable and interfere with usages. Meanwhile, more fans also mean consuming more power, more cost, even more heat.

The key point is making an active convection to introduce outside cool air into chassis and take heat out away. From now on, a new apparatus and method with simple and reasonable assembly solving foregoing problems will be disclosed.

### SUMMARY OF THE INVENTION

Accordingly, the primary object of the present invention is to provide a duct, covering the mainboard in chassis with two ends open and set with fan, to produce active convection introducing airflow in and out of chassis.

To achieve the object, the present invention provides an active convective air scoop cooling assembly. In one embodiment, a duct, form an air scoop, covering the mainboard and attached on chassis with two ends open. Part of electronic components on mainboard, like CPU or other highly heat dissipating components, are covered in the duct. With two ends of duct open on walls of chassis, a fan set in the duct can blow airflow through the duct guiding outside cool air in from one open end and taking heat to the other open end out away.

In one embodiment, the present invention comprises an extended movable swapping cover on the side of duct to fit second or more microprocessor and/or other heat dissipating electronic components.

For reduce buzz noise, in one embodiment, a soundproof stuff is laid in the duct to absorb sound of fan motor or airflow.

The various objects and advantages of the present invention will be more readily understood from the following detailed description when read in conjunction with the appended drawings.

### BRIEF DESCRIPTION OF THE DRAWINGS

FIG. 1 illustrates an exploded perspective view of an embodiment of this invention with dotted line indicating how the separate modules can be assembled;

FIG. 2 illustrates a profile of a first embodiment;

FIG. 3 illustrates a profile of a second embodiment;

FIG. 4 illustrates a view of the first embodiment attached in a computer chassis with arrows indicating the direction of assembling; and

FIG. 5 illustrates a lateral cross sectional view of the first embodiment attached in a computer chassis with arrows indicating the air flow through the module.

### DETAILED DESCRIPTION OF THE INVENTION

In the following, various aspects of embodiments of this invention are described with figures for further details.

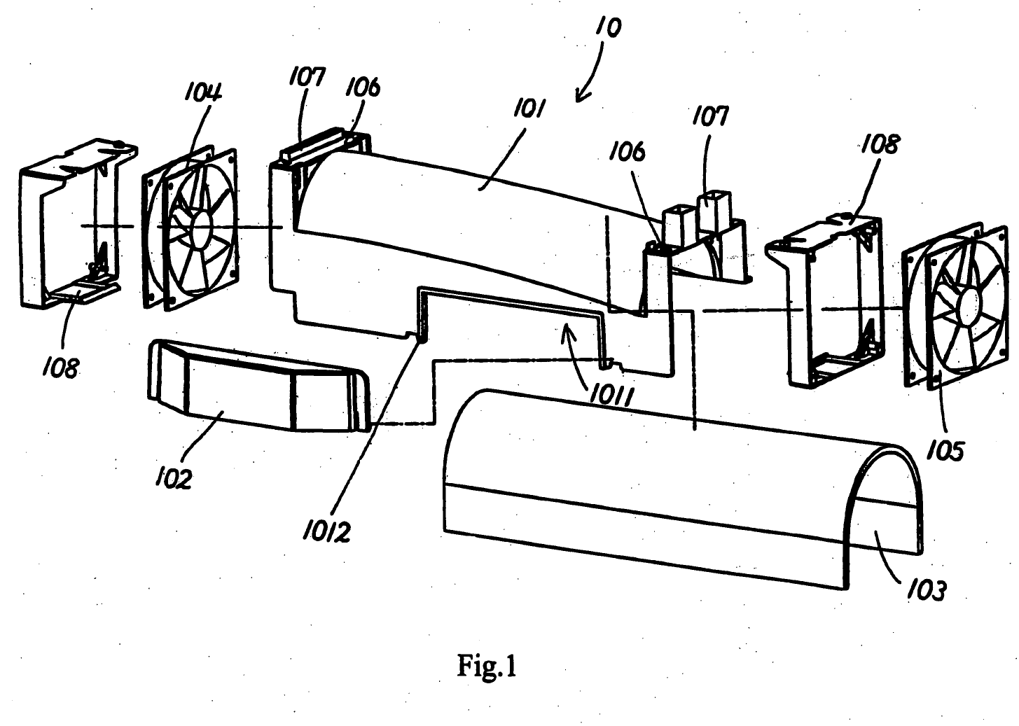

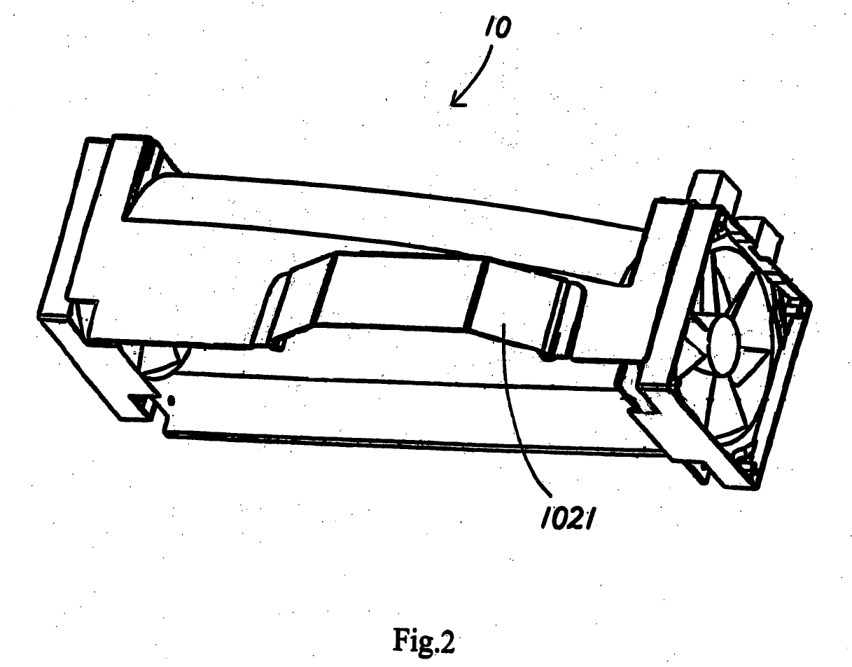

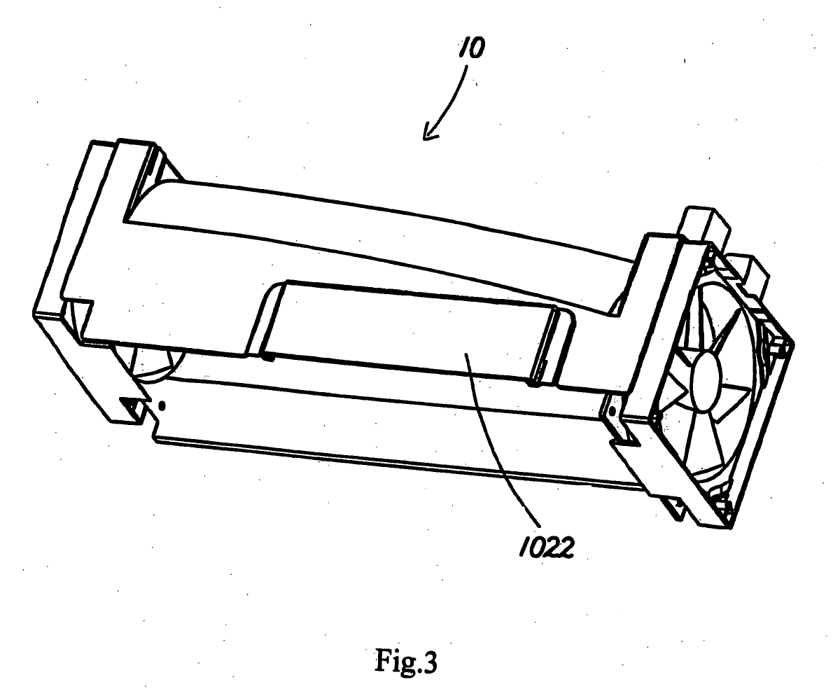

FIG. 1, FIG. 2, and FIG. 3, are exploded views of this invention, a profile of a first embodiment, and a second embodiment respectively. An active convective air scoop cooler 10 comprises a duct 101 and an extended movable swapping cover 102. The said duck 101 has soundproof stuff 103 laid inside, an air-intake fan 104 and an exhaust fan 105 installed appropriately at its two open ends. The air-intake fan 104 blows outside cool air into the duct 101 in the chassis, and the exhaust fan 105 blows warm air out of the chassis in the other side, so that an active convective airflow is formed inside the duct 101. A fastener module 106 at the ends of the duct 101 to fix in chassis and a protrusion 107 on the duct 101 is attached to chassis to avoid move of the duct 101. One of the bottom sides of the duct 101 comprises an indentation 1011, and also comprises a chamfer 1012. The extended movable swapping cover 102 wedges with the chamfer 1012 covering the indentation 1011 of the duct 101 to fit second or more microprocessor and/or other heat dissipating electronic components. In first embodiment referring to FIG. 2 the extended movable swapping cover 102 is a hood 1021, and in second embodiment referring to FIG. 3 the extended movable swapping cover 102 is a screen 1022. The hood 1021 wedged with the chamfer 1012 on the duct 101 extends the coverage of the duct 101 to fit with extra heat dissipating electronic components on the mainboard, like second CPU or microprocessor in the situation of a server, or wedged with the screen 1022 in normal use.

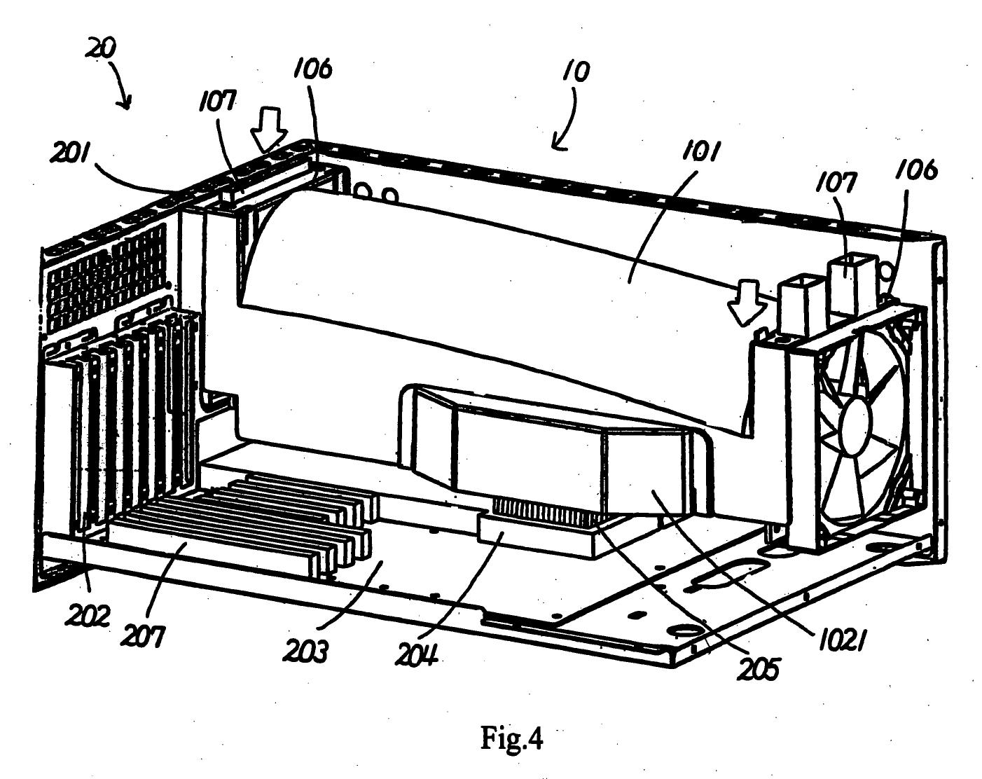

Referring to FIG. 4, in the situation of the first embodiment of this invention, illustrating a view of the complete active convective air scoop cooler 10 attached in a computer chassis 20, the duct 101 with the hood 1021 covers a dual CPU set 204 on a mainboard 203. When installing the active convective air scoop cooler 10 into the chassis 20, pushing the fastener module 106 at the ends of the duct 101 into side 201 of the chassis 20 is indicated by arrows, and the protrusions 107 on the duct 101 attach the side 201 to fix in the chassis 20.

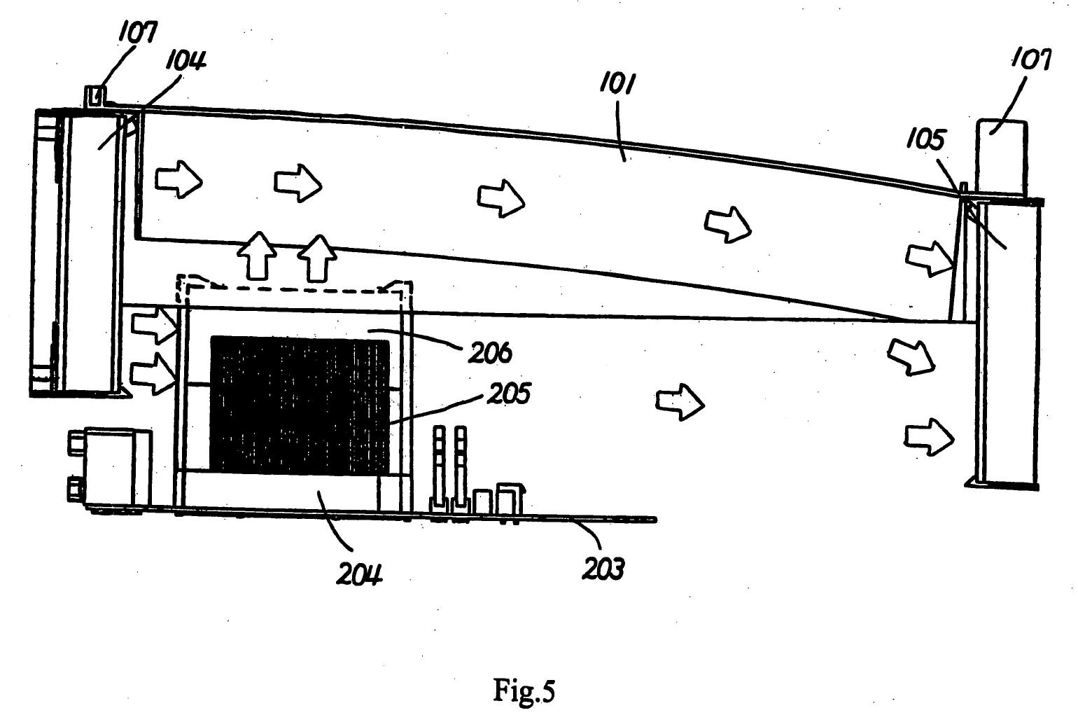

FIG. 5 illustrates the actual working skill of the first embodiment, and arrows indicate the way of airflow. The dual CPU set 204, with its cooler comprising a radiator 205 and a fan 206, and part of the mainboard 203 are in coverage of the duct 101. The fan 206 blows and takes heat of the dual CPU set 204 away via the radiator 205 into the duct 101. The air-intake fan 104 blows outside cool air into the duct 101 and the exhaust fan 105 blows warm air out in the other side, so that an active convective air is flowing in the duct 101 as arrows indicate and heat will neither remain in the closed chassis nor raise whole temperature, and in case of the fan's failure, whether the air-intake fan 104 or the exhaust fan 105, it can be exchanged even when system is running. Cool air blown by the air-intake fan 104 can be directed onto the radiator 205 to cool down. Furthermore, in this skill, the soundproof stuff 103 laid inside the duct 101 (not shown in FIG. 5) will reduce buzz noise of the fan 206, the air-intake fan 104 and the exhaust fan 105.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications intend to be embraced within the scope of the invention as defined in the appended claims.

1. An active convective air scoop cooler comprising:
an air scoop, fitting in chassis, with two ends open on chassis walls for air flowing;
a fan integrated into the air scoop to produce active airflow;
a fastener module to fix in chassis;
which is characterized in covering the mainboard in chassis, making airflow from outside low temperature air and taking inside heat out of chassis to cool microprocessors and/or other electronic components or devices on mainboard.

2. The active convective air scoop cooler of claim 1, wherein a soundproof stuff is laid inside the air scoop.

3. The active convective air scoop cooler of claim 1, wherein the fan set in open end of the air scoop to blow air into chassis.

4. The active convective air scoop cooler of claim 1, wherein the fan set in open end of the air scoop to blow air out of chassis.

5. The active convective air scoop cooler of claim 1, wherein the fan set inside the air scoop to blow air through chassis.

6. The active convective air scoop cooler of claim 1, wherein the fastener module working by tongue and groove.

7. The active convective air scoop cooler of claim 1, wherein the fastener module working by bolt.

8. The active convective air scoop cooler of claim 1, wherein the fastener module working by screw.

9. The active convective air scoop cooler of claim 1, wherein the air scoop comprising an extended movable swapping cover.

10. The active convective air scoop cooler of claim 9, wherein the extended movable swapping cover covering another extensible Central Processing Unit (CPU) and/or any other electronic components or devices on mainboard.
